(19) United States
(12) Patent Application Publication
(10) Pub. No.: US 2026/0164892 A1
(43) Pub. Date: Jun. 11, 2026

(54) ULTRATHIN TRANSPARENT ELECTRODE AND PREPARING METHOD OF THE SAME

(71) Applicants: POSTECH RESEARCH AND BUSINESS DEVELOPMENT FOUNDATION, Pohang-si (KR); North Carolina State University, Raleigh, NC (US)

(72) Inventors: Unyong JEONG, Pohang-si (KR); Minsik KONG, Pohang-si (KR); Michael DICKEY, Raleigh, NC (US); Man Hou VONG, Raleigh, NC (US)

(73) Assignees: POSTECH RESEARCH AND BUSINESS DEVELOPMENT FOUNDATION, Pohang-si (KR); North Carolina State University, Raleigh, NC (US)

(21) Appl. No.: 18/976,124

(22) Filed: Dec. 10, 2024

(51) Int. Cl. H10H 29/80; H10H 29/01

(52) U.S. Cl. CPC H10H 29/8321; H10H 29/032; H10H 29/8323

(57) ABSTRACT

Provided are an ultrathin transparent electrode and a method of manufacturing the ultrathin transparent electrode, and an ultrathin transparent electrode includes metal oxide of a first metal, an alloy of the first metal of the metal oxide and a second metal, and the first metal of the metal oxide that is not bonded to the second metal.

### BACKGROUND

### 1. Field of the Invention

One or more embodiments relate to an ultrathin transparent electrode and a method of manufacturing the ultrathin transparent electrode.

### 2. Description of the Related Art

Amorphous metal oxides (AMOs) have a variety of useful properties for optoelectronics, digital memory devices, and thin film transistors due to high carrier mobility and optical transparency. Traditionally, AMOs are generally deposited through chemical/physical vapor deposition. The existing deposition methods typically require a vacuum environment, a highly toxic precursor gas, and long process time.

AMOs may be easily used on a surface of gallium-based a liquid metal (LM). The metal is present as a liquid at or near room temperature and in its natural form due to rapid oxidation in air.

AMOs on the surface of LM are self-passivating and very thin (<5 nm). However, unlike organometallic precursors of the related art for AMO deposition, gallium-based LM have very low toxicity and a vapor pressure thereof is practically 0. Therefore, researchers have researched to use this feature to develop new and low-cost methods to print these AMOs from a host LM.

Recently, a method of delaminating amorphous gallium oxide (GaOx) from LM through van der Waals (VdW) delamintaion has been developed as a method of depositing a GaOx thin film. Specifically, the GaOx thin film is delaminated by gently contacting LM droplets and then removing a substrate from the droplets. A squeegee/rolling method is essentially another method of depositing GaOx from LM by rubbing the metal across the surface. When this method is used, GaOx of a large area may be deposited by scraping a puddle of LM onto a substrate using a soft (e.g., silicon) scraper or roller. However, this method has some problems. For example, VdW delamination generally separates an oxide film from small LM droplets, which may limit the size of the delaminated GaOx. On the other hand, the “squeegee/rolling” method may allow for large-area GaOx printing, but there is a problem that a significant amount of LM residue remains after printing, which may deteriorate performance of the printed oxide.

The above description has been possessed or acquired by the inventor(s) in the course of conceiving the present disclosure and is not necessarily an art publicly known before the present application is filed.

### SUMMARY

Embodiments to solve the above-described problems, and provide an ultrathin transparent electrode with a surface where cracks are not generated even when deformed due to an extremely small thickness and high density and a method of manufacturing the ultrathin transparent electrode by a simple method on a desired substrate regardless of the type of substrate.

However, technical goals to be achieved are not limited to those described above, and other goals not mentioned above may be clearly understood by one of ordinary skill in the art from the following description.

According to an aspect, there is provided an ultrathin transparent electrode including metal oxide of a first metal, an alloy of the first metal of the metal oxide and a second metal, and the first metal of the metal oxide that is not bonded to the second metal.

The first metal may include a liquid metal, and the LM may include at least one selected from the group consisting of gallium (Ga), indium (In), tin (Sn), zinc (Zn), eutectic gallium-indium (EGaIn), gallium-aluminum (Ga—Al), gallium-tin (Ga—Sn), gallium-zinc (Ga—Zn), and gallium-aluminum (Ga—Al).

The metal oxide may include at least one selected from the group consisting of GaOx, Ga₂O₃, InOx, AlOx, SnO₂, and ZnO.

The second metal may include gold (Au), copper (Cu), or both.

The ultrathin transparent electrode may have a thickness of 500 μm or less.

The ultrathin transparent electrode may be configured as a single layer.

The ultrathin transparent electrode may be amorphous.

The ultrathin transparent electrode may have a sheet resistance of 30 Ω/sq to 1,000 Ω/sq, and the ultrathin transparent electrode may have optical transparency of 85% to 99%.

According to another aspect, there is provided a method of manufacturing an ultrathin transparent electrode, the method including preparing a metal oxide thin film of a first metal, depositing a second metal on the metal oxide thin film, and annealing the metal oxide thin film on which the second metal is deposited.

The first metal may include a LM, and the LM may include at least one selected from the group consisting of gallium (Ga), indium (In), tin (Sn), zinc (Zn), eutectic gallium-indium (EGaIn), gallium-aluminum (Ga—Al), gallium-tin (Ga—Sn), gallium-zinc (Ga—Zn), and gallium-aluminum (Ga—Al).

The metal oxide may include at least one selected from the group consisting of GaOx, Ga₂O₃, InOx, AlOx, SnO₂, and ZnO.

The second metal may include gold (Au), copper (Cu), or both.

The preparing of the metal oxide thin film of the first metal may include filling a first metal into a printer head including two glass substrates spaced apart from each other, and preparing the metal oxide thin film of the first metal by moving the printer head on a substrate along a longitudinal direction of the substrate.

In the preparing of the metal oxide thin film of the first metal, an upper metal oxide layer and a lower metal oxide layer may be formed respectively on an upper portion where the first metal filled between the two glass substrates of the printer head comes out of the printer head and contacts the air and a lower portion where the first metal comes out of the printer head and contacts the substrate, and an LM layer containing a residual LM may be interposed between the upper metal oxide layer and the lower metal oxide layer.

The preparing of the metal oxide thin film of the first metal may be performed by at least one method selected from the group consisting of atomic layer deposition (ALD), molecular beam epitaxy (MBE), pulsed laser deposition (PLD), and sputtering.

A proportion of a metal layer in the metal oxide thin film may be in excess of 18% or more.

The depositing of the second metal on the metal oxide thin film may be performed at a temperature of 10° C. to 200° C. and a pressure range of 10-5 torr to 10-7 torr.

In the preparing of the metal oxide thin film of the first metal, a speed of moving the printer head on the substrate along the longitudinal direction of the substrate may be 0.001 mm/s to 5 mm/s.

The depositing of the second metal on the metal oxide thin film may include partially depositing a metal patterned through a mask.

The annealing of the metal oxide thin film on which the second metal is deposited may be performed at a temperature of 50° C. to 1,500° C. and a pressure range of 760 torr to 10-7 torr.

The metal may be formed, by the annealing, as a single layer including an alloy of the first metal of the metal oxide and the second metal, the metal oxide, and the first metal of the metal oxide that is not bonded to the second metal.

According to still another aspect, there is provided an electronic device including the ultrathin transparent electrode according to an embodiment of the present disclosure, or an ultrathin transparent electrode manufactured by the method of manufacturing the ultrathin transparent electrode according to another embodiment of the present disclosure.

Additional aspects of embodiments will be set forth in part in the description which follows and, in part, will be apparent from the description, or may be learned by practice of the disclosure.

An ultrathin transparent electrode according to an embodiment of the present disclosure has high conductivity, extremely small thickness, and high density, and therefore cracks are not generated on a surface even deformation occurs. Accordingly, the ultrathin transparent electrode may be used as an ultrathin circuit board.

In a method of manufacturing the ultrathin transparent electrode according to an embodiment of the present disclosure, a flexible transparent electrode with high conductivity may be easily manufactured by a simple method of depositing a very small amount of metal on a metal oxide thin film printed over a large area, regardless of the type of substrate. In addition, the metal oxide film itself may be used as an ultrathin circuit board by depositing the metal only on a desired portion. Because of its high usability, it has high applicability as a display substrate and an electrode.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a cross-sectional view schematically illustrating an ultrathin transparent electrode according to an embodiment of the present disclosure;

FIG. 2A is a flowchart illustrating a method of manufacturing an ultrathin transparent electrode according to an embodiment of the present disclosure;

FIG. 2B is a flowchart specifically illustrating a metal oxide thin film preparation step of FIG. 2A;

FIG. 3 is a diagram schematically illustrating a printing apparatus for manufacturing a metal oxide thin film according to an embodiment of the present disclosure;

FIG. 4A is an image of a printing apparatus used in an embodiment of the present disclosure;

FIG. 4B illustrate images of gallium oxide thin film electrodes printed on various substrates according to an embodiment of the present disclosure;

FIGS. 5A and 5B illustrate planar scanning electron microscopy (SEM) images and cross-sectional transmission electron microscopy (TEM) and energy dispersive X-ray spectroscopy (EDS) images in which gold (Au) (4 nm) is deposited on a printed GaOx metal oxide film according to an embodiment of the present disclosure;

FIG. 6A is a diagram illustrating conductivity when gold (Au) or copper (Cu) having a thickness of 4 nanometers (nm) is deposited on a single printed gallium oxide film according to an embodiment of the present disclosure;

FIG. 6B is a diagram illustrating resistance when gold (Au) or copper (Cu) having a thickness of 4 nm is deposited on a single printed gallium oxide film according to an embodiment of the present disclosure;

FIG. 7A is a diagram comparing results of commercial flexible indium tin oxide (ITO) (thickness: 115 nm) coated on a polyethylene terephthalate (PET) substrate (thickness: 175 micrometers (μm)) and an Au/GaOx film coated on a polyimide (PI) film (thickness: 5μm) according to an embodiment of the present disclosure;

FIG. 7B is an optical image of a scratch notch of Au/GaOx/PI according to an embodiment of the present disclosure;

FIG. 8A is a diagram schematically illustrating a manufacturing process of an ultrathin circuit board according to an embodiment of the present disclosure;

FIG. 8B is an optical microscope image of a mesh electrode manufactured according to an embodiment of the present disclosure;

FIG. 8C is a diagram illustrating optical transparency and conductivity of a mesh electrode manufactured according to an embodiment of the present disclosure;

FIG. 9A is an optical image after transferring an ultrathin transparent circuit board onto a leaf according to an embodiment of the present disclosure;

FIG. 9B is a SEM image after transferring an ultrathin transparent circuit board onto a leaf according to an embodiment of the present disclosure;

FIG. 9C is an image illustrating conductivity of a circuit line of an ultrathin transparent circuit board that is transferred onto a leaf according to an embodiment of the present disclosure;

FIG. 10A is an optical image of a display manufactured using a light emitting diode (LED) manufactured according to an embodiment of the present disclosure;

FIG. 10B is an optical image of a display manufactured using an LED manufactured according to an embodiment of the present disclosure when the display is crumpled; and

FIG. 10C is an optical image of a display manufactured using an LED manufactured according to an embodiment of the present disclosure when the display is folded.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one component from another component, and the nature, the sequences, or the orders of the components are not limited by the terms.

The same name may be used to describe an element included in the embodiments described above and an element having a common function. Unless otherwise mentioned, the descriptions on the embodiments may be applicable to the following embodiments and thus, duplicated descriptions will be omitted for conciseness.

Hereinafter, an ultrathin transparent electrode and a method of preparing an ultrathin transparent electrode will be described in detail with reference to embodiments and drawings. However, the present disclosure is not limited to the embodiments and drawings.

An ultrathin transparent electrode according to an embodiment of the present disclosure includes metal oxide of a first metal, an alloy of the first metal of the metal oxide and a second metal, and the first metal of the metal oxide that is not bonded to the second metal.

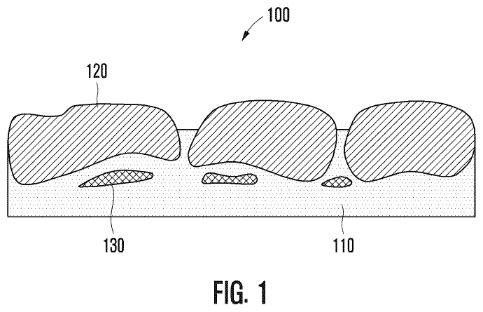

FIG. 1 is a cross-sectional view schematically illustrating an ultrathin transparent electrode according to an embodiment of the present disclosure.

Referring to FIG. 1, an ultrathin transparent electrode 100 according to an embodiment of the present disclosure includes metal oxide 110 of a first metal, an alloy 120 of the first metal of the metal oxide and a second metal, and a first metal 130 of the metal oxide that is not combined with the metal.

In an embodiment, the metal oxide 110 may be oxide of the first metal.

In an embodiment, the first metal may be a liquid metal (LM).

The LM may include at least one selected from the group consisting of gallium (Ga), indium (In), tin (Sn), zinc (Zn), eutectic gallium-indium (EGaIn), gallium-aluminum (Ga—Al), gallium-tin (Ga—Sn), gallium-zinc (Ga—Zn), and gallium-aluminum (Ga—Al).

The first metal may be desirably gallium (Ga).

In an embodiment, the metal oxide 110 may include at least one selected from the group consisting of GaOx, Ga₂O₃, InOx, AlOx, SnO₂, and ZnO.

The metal oxide may be desirably GaOx.

In an embodiment, the second metal may include gold (Au), copper (Cu), or both.

The second metal may be desirably gold (Au).

In an embodiment, the ultrathin transparent electrode 100 may have a thickness of 500 micrometers (μm) or less; 400 μm or less; 300 μm or less; 200 μm or less; 100μm or less; 50 μm or less; 1 μm or less; 100 nanometers (nm) or less; or 10 nm or less.

The ultrathin transparent electrode 100 may have a thickness of at least 1 nm.

In an embodiment, the ultrathin transparent electrode 100 may be a single layer. The ultrathin transparent electrode of the present disclosure may be a single layer in which the metal oxide 110, the alloy 120 of the first metal of the metal oxide and the second metal, and the first metal 130 of the metal oxide that is not bonded to the metal are randomly arranged with no boundaries, rather than being composed of those as individual layers.

In an embodiment, the ultrathin transparent electrode 100 may be amorphous.

The ultrathin transparent electrode of the present disclosure being amorphous may be confirmed by observing the absence of rings or dots showing long-range order of a specific crystal plane seen in a crystalline material with a transmission electron microscope (TEM) with a pattern of selected-area electron diffraction (SAED).

In an embodiment, the ultrathin transparent electrode 100 may have sheet resistance of 30 Ω/sq to 1,000 Ω/sq; 30 Ω/sq to 800 Ω/sq; 30 Ω/sq to 500 Ω/sq; 30 Ω/sq to 300 Ω/sq; 30 Ω/sq to 100 Ω/sq; 50 Ω/sq to 1,000 Ω/sq; 50 Ω/sq to 800 Ω/sq; 50 Ω/sq to 500 Ω/sq; 50 Ω/sq to 300 Ω/sq; 50 Ω/sq to 100 Ω/sq; 100 Ω/sq to 1,000 Ω/sq; 100 Ω/sq to 800 Ω/sq; 100 Ω/sq to 500 Ω/sq; 100 Ω/sq to 300 Ω/sq; 300 Ω/sq to 1,000 Ω/sq; 300 Ω/sq to 800 Ω/sq; 300 Ω/sq to 500 Ω/sq; 500 Ω/sq to 1,000 Ω/sq; 500 Ω/sq to 800 Ω/sq; or 800 Ω/sq to 1,000 Ω/sq.

When the sheet resistance of the transparent oxide electrode is less than 30 Ω/sq, a problem of being lower than a minimum value of measured values in an experiment may occur, and when the sheet resistance thereof exceeds 1,000 Ω/sq, a problem of being higher than a maximum value of measured values in an experiment may occur.

The ultrathin transparent electrode may have optical transparency of 85% to 99%. The optical transparency may be measured in a visible light range (400 to 700 nm).

The ultrathin transparent electrode according to an embodiment of the present disclosure has high conductivity, extremely small thickness, and high density, and therefore cracks are not generated on a surface even deformation occurs. Accordingly, the ultrathin transparent electrode may be used as an ultrathin circuit board.

A method of manufacturing an ultrathin transparent electrode according to another embodiment of the present disclosure includes preparing a metal oxide thin film of a first metal, depositing a second metal on the metal oxide thin film, and annealing the metal oxide thin film on which the second metal is deposited.

A transparent oxide electrode of the related art is formed in a form of a surface inside of which is filled with a transparent oxide electrode material such as ITO. Accordingly, it is necessary to perform a plurality of steps such as deposition, drying, exposure, development, etching, and the like to cause transparent electrodes to be spaced apart from each other. Thus, the production line may become more complex and the production cost may increase because devices are needed for each process. On the other hand, the transparent oxide film electrode according to the present disclosure is formed by a simple printing process, and a device used in the process also has a simple configuration. Accordingly, the production line may be simplified, the production cost may be reduced, and the process efficiency may be increased. Particularly, this effect may be further enhanced when implemented on a large scale.

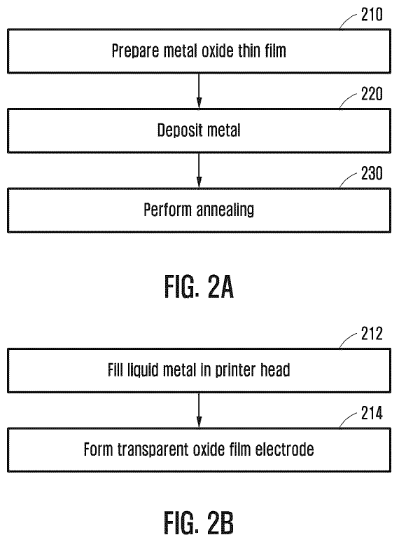

FIG. 2A is a flowchart illustrating a method of manufacturing an ultrathin transparent electrode according to an embodiment of the present disclosure, and FIG. 2B is a flowchart specifically illustrating a metal oxide thin film preparation step of FIG. 2A.

Referring to FIGS. 2A and 2B, the method of manufacturing an ultrathin transparent electrode according to an embodiment of the present disclosure includes step 210 of preparing a metal oxide thin film of a first metal, step 220 of depositing a second metal, and step 230 of annealing.

Step 210 of preparing the metal oxide thin film of the first metal may include step 212 of filling the first metal into a printer head including two glass substrates spaced apart from each other, and step 214 of preparing the metal oxide thin film of the first metal by moving the printer head on a substrate along a longitudinal direction of the substrate.

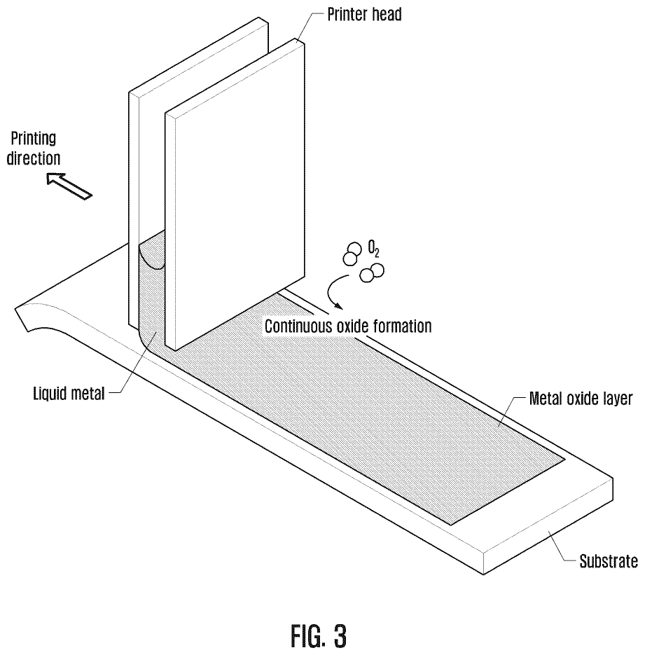

FIG. 3 is a diagram schematically illustrating a printing apparatus for manufacturing a metal oxide thin film according to an embodiment of the present disclosure.

As shown in FIG. 3, in step 212 of filling the first metal into the printer head, an LM may be filled between two spaced glass substrates of the printer head.

In an embodiment, the metal oxide may be oxide of the first metal.

In an embodiment, the first metal may be an LM.

The LM may include one selected from the group consisting of gallium (Ga), indium (In), tin (Sn), zinc (Zn), eutectic gallium-indium (EGaIn), gallium-aluminum (Ga—Al), gallium-tin (Ga—Sn), and gallium-zinc (Ga—Zn).

The first metal may be desirably gallium (Ga) or gallium-aluminum (Ga—Al).

In step 214 of preparing the metal oxide thin film of the first metal, the metal oxide thin film may be formed by moving the printer head on the substrate along the longitudinal direction (a printing direction of FIG. 3) of the substrate.

In an embodiment, the substrate may include at least one selected from the group consisting of silicon (Si), silicon oxide (SiO₂), aluminum oxide (Al₂O₃), magnesium oxide (MgO), silicon carbide (SiC), silicon nitride (SiN), glass, quartz, sapphire, graphite, graphene, PI, polyester (PE), polyethyleneterephthalate (PET), poly(2,6-ethylenenaphthalate) (PEN), polymethyl methacrylate (PMMA), polyurethane (PU), fluoropolymers (FEP), polyvinylidene fluoride (PVDF), polydimethylsiloxane (PDMS), and an Au film processed with (3-mercaptopropyl)trimethoxysilane (MPTMS).

In an embodiment, in the step of preparing the metal oxide thin film of the first metal, an upper metal oxide layer and a lower metal oxide layer may be formed respectively on an upper portion where the first metal filled between the two glass substrates of the printer head comes out of the printer head and contacts the air and a lower portion where the first metal comes out of the printer head and contacts the substrate, and an LM layer containing a residual LM may be interposed between the upper metal oxide layer and the lower metal oxide layer.

In an embodiment, in the step of preparing the metal oxide thin film of the first metal, a speed of moving the printer head on a substrate along a longitudinal direction of the substrate may be 0.001 mm/s to 5 mm/s; 0.001 mm/s to 1 mm/s; 0.001 mm/s to 0.1 mm/s; 0.001 mm/s to 0.01 mm/s; 0.01 mm/s to 5 mm/s; 0.01 mm/s to 1 mm/s; 0.01 mm/s to 0.1 mm/s; 0.1 mm/s to 5 mm/s; 0.1 mm/s to 1 mm/s; or 1 mm/s to 5 mm/s. When the moving speed is less than 0.001 mm/s, the moving speed may be lower than a minimum speed of printing equipment, and when the moving speed exceeds 5 mm/s, the moving speed may exceed a threshold speed at which printing is theoretically possible.

In an embodiment, the formed metal oxide may include at least one selected from the group consisting of GaOx, Ga₂O₃, InOx, AlOx, SnO₂, and ZnO.

In an embodiment, the second metal may include gold (Au), copper (Cu), or both.

The metal oxide thin film may be manufactured through a printing process, and thus, when it is developed into a roll-to-roll process in the future, it may be mass-produced on a large area. In addition, an extremely thin and high-density film is formed, and cracks are not generated on the surface even when deformed.

The metal oxide thin film manufactured by filling the LM between the two spaced glass substrates of the printer head may include an upper metal oxide layer; a lower metal oxide layer; and a first metal layer including a first residual metal interposed between the upper metal oxide layer and the lower metal oxide layer.

In an embodiment, the step of preparing of the metal oxide thin film of the first metal may be performed by at least one method selected from the group consisting of atomic layer deposition (ALD), molecular beam epitaxy (MBE), pulsed laser deposition (PLD), and sputtering.

Metal oxide thin films and metal thin films may be alternately formed by the methods, however, these may be formed by purging various types of metal-organic precursors, or a multi-step process may be required through adjustment of an oxygen concentration at the time of deposition.

In an embodiment, a proportion of the metal layer in the metal oxide thin film may be included in excess of 18% or more. When the proportion of the metal layer is less than 5%, an alloying reaction between gallium and the metal deposited on the upper portion may be insufficient.

Step 220 of depositing may be performed at a temperature of 10° C. to 200° C.; 10° C. to 180° C.; 10° C. to 150° C.; 10° C. to 130° C.; 10° C. to 100° C.; 50° C. to 200° C.; 50° C. to 180° C.; 50° C. to 150° C.; 50° C. to 130° C.; 50° C. to 100° C.; 100° C. to 200° C.; 100° C. to 180° C.; 100° C. to 150° C.; 100° C. to 130° C.; 130° C. to 200° C.; 130° C. to 180° C.; 130° C. to 150° C.; 150° C. to 200° C.; 150° C. to 180° C.; or 180° C. to 200° C.; and in a pressure range of 10-5 torr to 10-7 torr.

When performing the deposition at a temperature lower than 10° C. and a pressure lower than 10-5 torr, it is necessary to install an additional cooler in deposition equipment, or additional oxidation or uneven deposition quality problems due to low vacuum may occur, and when performing the deposition at a temperature higher than 200° C. and a pressure higher than 10-7 torr, a problem such as oxidation or sample damage due to a high temperature may occur, and additional high vacuum equipment may need to be installed.

The metal may be deposited with a thickness of 10 nm or less; 8 nm or less; desirably 5 nm or less. The thickness is a final thickness of gold to be deposited.

In general, when metal is deposited on a substrate, it is deposited in a form of metal nanoparticles rather than in a form of a thin film, and when a larger amount thereof is deposited, a film may be formed with these particles connected with each other.

In an embodiment, the step of depositing the second metal on the metal oxide thin film may include partially depositing patterned gold through a mask. When a very small amount of metal is deposited only on a desired portion on the metal oxide thin film through a mask and heat-treated, metal lines may be insulated and the portion where the second metal is deposited may maintain conductivity. In addition, it may be transferred to leaves with an uneven surface, and may also be used as a flexible transparent electrode whose properties do not change even when folded.

Step 230 of annealing the metal oxide thin film on which the second metal is deposited may be performed at a temperature of 50° C. to 1,500° C.; 50° C. to 1,000° C.; 50° C. to 800° C.; 50° C. to 500° C.; 50° C. to 300° C.; 50° C. to 100° C.; 100° C. to 1,500° C.; 100° C. to 1,000° C.; 100° C. to 800° C.; 100° C. to 500° C.; 100° C. to 300° C.; 300° C. to 1,500° C.; 300° C. to 1,000° C.; 300° C. to 800° C.; 300° C. to 500° C.; 500° C. to 1,500° C.; 500° C. to 1,000° C.; 500° C. to 800° C.; 800° C. to 1,500° C.; 800° C. to 1,000° C.; or 1,000° C. to 1,500° C. and in a pressure range of 760 torr to 10-7 torr.

When the annealing temperature is lower than 50° C., the annealing effect may not be achieved, and when the annealing temperature exceeds 1,500° C., a maximum temperature range of a furnace, which is general annealing equipment, may be exceeded.

In an embodiment, by the annealing, the metal may be formed as a single layer of an alloy of a first metal and a second metal of the metal oxide, the metal oxide, and the first metal of the metal oxide that is not bonded to the second metal.

In the method of manufacturing the ultrathin transparent electrode according to an embodiment of the present disclosure, a flexible transparent electrode with high conductivity may be manufactured by a simple method of depositing a very small amount of metal on a metal oxide thin film printed over a large area, regardless of the type of substrate. In addition, the metal oxide film itself may be used as an ultrathin circuit board by depositing the metal only on a desired portion. Because of its high usability, it has high applicability as a display substrate and an electrode.

An electronic device according to still another embodiment of the present disclosure includes the ultrathin transparent electrode according to an embodiment of the present disclosure, or an ultrathin transparent electrode manufactured by the method of manufacturing the ultrathin transparent electrode according to another embodiment.

In an embodiment, the electronic device may be a packaging device, a digital memory device, a thin film transistor, a flat panel display, a curved display, a touch screen panel, a solar cell, an organic light emitting diode (LED), a smartphone, a tablet personal computer (PC), a wearable device, an e-paper, an e-window, an electrochromic mirror, a transparent heater, a heat mirror, a transparent heater, a transparent transistor, a transparent strain sensor, or a flexible display.

Hereinafter, the present disclosure will be described in detail with reference to the following examples and comparative examples. However, the technical idea of the present disclosure is not limited or restricted thereto.

### Examples

A printer head of a printing apparatus for manufacturing a metal oxide thin film shown in FIG. 3 was prepared by attaching two glass slides at interval of 1 mm. A metal source was prepared by melting pellets at a temperature higher than equal to a melting point and injecting them into the printer head. A Ga—In eutectic alloy was manufactured by adding 25 wt % of In pellets to a Ga melt. A Ga—Al eutectic alloy was manufactured by adding 1 wt % of an Al powder to a Ga melt. Before adding the Al powder, surface oxide was broken by crushing with a mortar. A polymer substrate was prepared by directly spin-coating a solution onto a desired substrate. For a gold substrate, Au having a thickness of 100 nm was deposited on the glass slide and treated with MPTMS to avoid metal-metal contact. 200 μl of MPTMS was dropped onto a glass petri dish and deposited in a vacuum chamber for 2 hours. The vapor-treated sample was washed with isopropyl alcohol (IPA) and DI water to remove any remaining chemicals. Hydrolysis and condensation of MPTMS treated on gold were carried out by soaking in dilute hydrochloric acid (3 wt %) for 1 hour and then rinsing with DI water. The substrate treated with MPTMS was finally annealed on a hot plate (100° C.) for an additional time. All substrates, including silicon wafers, c-plane sapphire, and quartz, were used after cleaning with solvents in the order of acetone, IPA, and DI water before use. LM was injected into the printer head between two glass slides using a syringe. The printer head including the LM was approached to a target substrate until the LM meniscus contacted the substrate. When the printer head touches the substrate, the printer head was raised to a desired height (h). Printing was performed by moving the printer head or moving a print at a desired speed. Multilayer stacking was performed by repeating the same printing process at the same position.

### Experimental Example 1

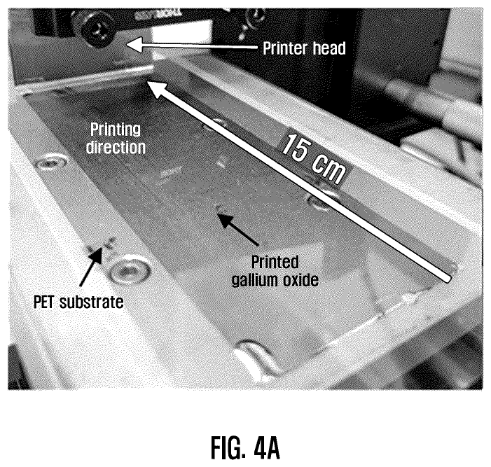

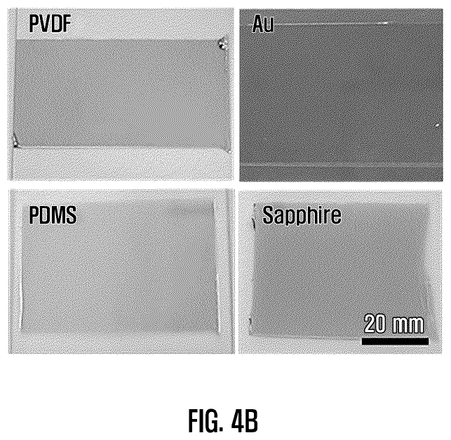

FIG. 4A is an image of a printing apparatus used in an embodiment of the present disclosure.

Gallium (Ga), as LM, was filled between two glass plates that function as a printer head, similar to slot die printing. The substrate and printer head were heated to a melting temperature of the metal source, and printing was performed by moving the printer head over the substrate to form a meniscus and then turning it off. On the back of the printer head, an oxide thin film is transferred to the substrate without an LM layer. As shown in FIG. 4A, the oxide thin film with a large area (>5 cm×15 cm) was printed by single print using a printer head with a width of 5 cm.

FIG. 4B illustrate images of gallium oxide thin film electrodes printed on various substrates according to an embodiment of the present disclosure.

As shown in FIG. 4B, it was confirmed that oxide thin films may be transferred independently on PVDF, an MPTMS-treated Au film, PDMS, and a sapphire substrate.

### Experimental Example 2

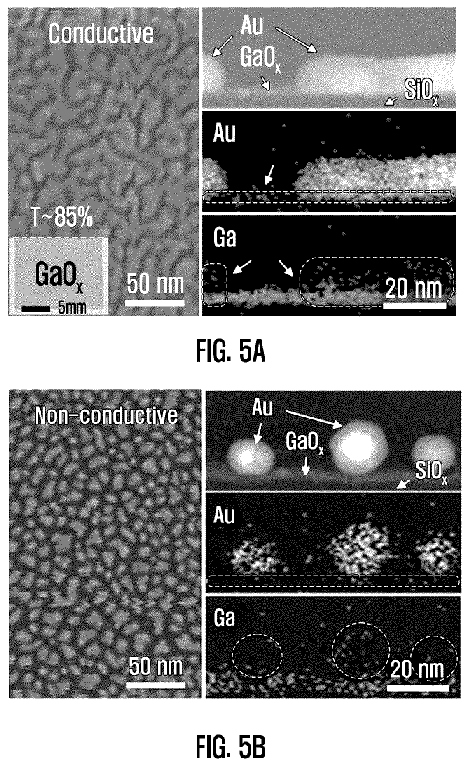

FIGS. 5A and 5B illustrate planar scanning electron microscopy (SEM) images and cross-sectional transmission electron microscopy (TEM) and energy dispersive X-ray spectroscopy (EDS) images in which gold (Au) (4 nm) is deposited on a printed GaOx metal oxide film according to an embodiment of the present disclosure.

Gold (Au) crystals have good wettability to an oxide film and are connected to each other. When gold (Au) was deposited on an already oxidized gallium oxide film by annealing at 80° C., the gold (Au) crystals were dewetted into spherical nanoparticles and were not connected to each other, which is a phenomenon commonly observed when deposited on an oxide surface.

The EDS results of FIG. 5A show the interdiffusion of gallium (Ga) and gold (Au) (arrows and dotted lines), indicating the formation of an Au-Ga alloy or Au-doped GaOx. In contrast, the EDS results of FIG. 5B show that gold (Au) was not diffused in an oxide layer of the pre-oxidized film and gallium (Ga) diffusion into gold (Au) was relatively limited.

### Experimental Example 3

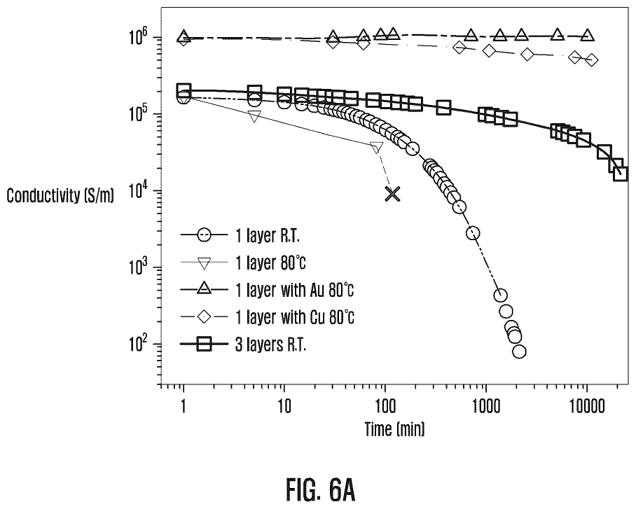

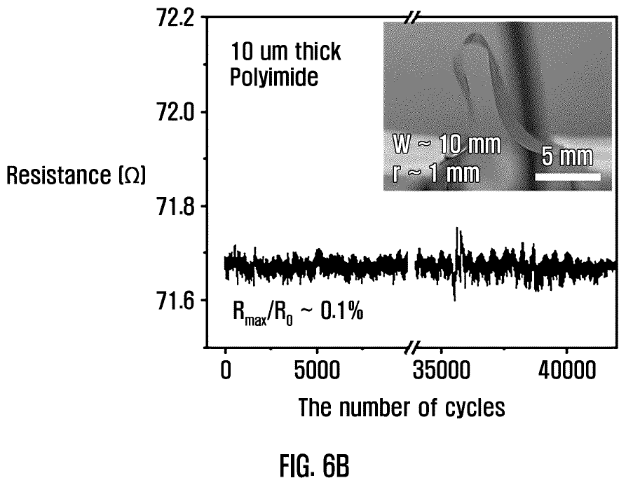

FIG. 6A is a diagram illustrating conductivity when gold (Au) or copper (Cu) having a thickness of 4 nm is deposited on a single printed gallium oxide film according to an embodiment of the present disclosure.

Referring to FIG. 6A, the conductivity increased to 1.0×10⁶ S/m, which was about 10 times higher than that of the printed oxide film, and the gold (Au)-deposited film showed no change in conductivity even after heat treatment is performed at 80° C. for 14 days. A copper (Cu)-deposited film showed a slight decrease in conductivity to 5×10⁵ S/m after annealing at 80° C. for 14 days, which may be due to additional oxidation of Cu.

FIG. 6B is a diagram illustrating a change in resistance due to folding of a single printed gallium oxide film in which gold (Au) having a thickness of 4 nm is deposited on a PI substrate having a thickness of 10 μm according to an embodiment of the present disclosure. It may be confirmed that negligible resistance change is shown without mechanical fatigue in 40,000 out-folding cycles at a bending radius of 1 mm (Rmax/Ro=0.1%).

### Experimental Example 4

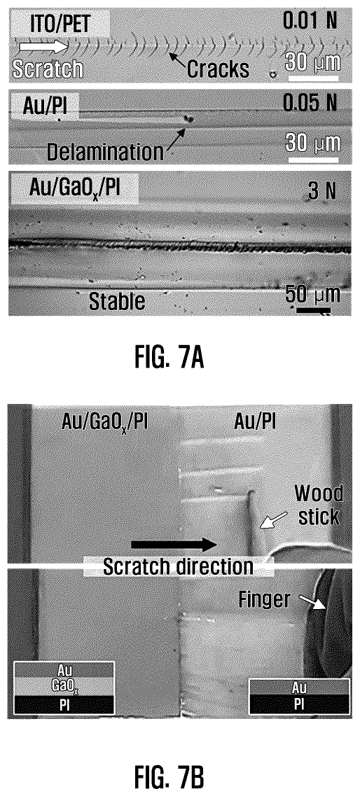

FIG. 7A is a diagram comparing results of commercial flexible ITO (thickness: 115 nm) coated on a PET substrate (thickness: 175 μm) and an Au/GaOx film coated on a PI film (thickness: 5 μm) according to an embodiment of the present disclosure, and FIG. 7B is an optical image of a scratch notch of Au/GaOx/PI according to an embodiment of the present disclosure.

As shown in FIG. 7A, the optical image of the scratch notch on ITO/PET showed cracking at low vertical force (0.01 N) due to brittleness. However, the Au/GaOx layer showed excellent mechanical durability, with no noticeable cracking or delamination even under a vertical force of 3 N. At this time, it may be noted that an Au film without the GaOx layer is easily delaminated at 0.05 N. As shown in FIG. 7B, when scratching was performed with a wooden stick and a finger to simulate actual usability, scratches were observed only in portions without the GaOx oxide film.

### Experimental Example 5

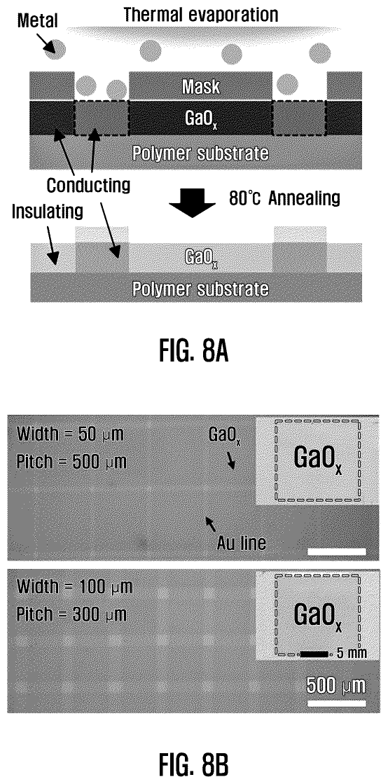

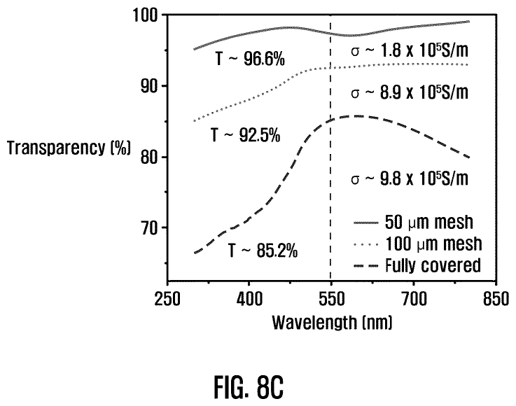

FIG. 8A is a diagram schematically illustrating a manufacturing process of an ultrathin circuit board according to an embodiment of the present disclosure.

As shown in FIG. 8A, gold (Au) was selectively deposited on a printed gallium oxide thin film through a mask and post-annealing was performed at 80° C. to manufacture an ultrathin circuit board. Most of polymer substrates of the related art may be used in this process due to the mild annealing conditions. Areas without gold (Au) deposition may be in an insulating state after the post-annealing, thereby blocking electrical connections between conductive patterns. The electrical conductivity of the patterned circuit lines was not changed according to a pattern width and was maintained at 1.0×10⁶ S/m for the pattern widths of 200 μm, 100 μm, and 50 μm. It was confirmed that a transparent electrode may be manufactured by depositing gold (Au) in a mesh shape. Gold (Au) (4 nm) was deposited through a line mask at a regular interval, and then deposited again after rotating the mask by 90° to manufacture a mesh electrode.

FIG. 8B is an optical microscope image of a mesh electrode manufactured according to an embodiment of the present disclosure.

Referring to FIG. 8B, a mesh electrode manufactured through a line mask having two types of spacing may be confirmed. An image inserted on the upper right portion is an image obtained after placing the mesh electrode in front of paper printed with “GaOx” to confirm transparency of the mesh electrode manufactured as described above.

FIG. 8C is a diagram illustrating optical transparency and conductivity of a mesh electrode manufactured according to an embodiment of the present disclosure.

Referring to FIG. 8C, the mesh with a width of 50 μm and a pitch of 500 μm showed a conductivity of 1.8×10⁵ S/m and optical transparency of 96.6% at a wavelength of 550 nm. The mesh with a width of 100 μm and a pitch of 300 μm showed the transparency of 92.5% and the conductivity of 8.9×10⁵ S/m, and exhibited excellent performance than the state-of-the-art performance of commercial TCO.

### Experimental Example 6

An ultrathin transparent circuit board may be transferred to a desired substrate by introducing a sacrificial layer. A single printed oxide film was printed on a poly(acrylic acid) (PAA) film that is a water-soluble polymer, gold (Au) was deposited through a mask, and then poly(methyl methacrylate) (PMMA, thickness: 500 nm) was spin-coated on the ultrathin transparent circuit board. Then, the PAA layer was dissolved in water, the circuit board was transferred to a desired substrate, and the PMMA layer was removed with acetone.

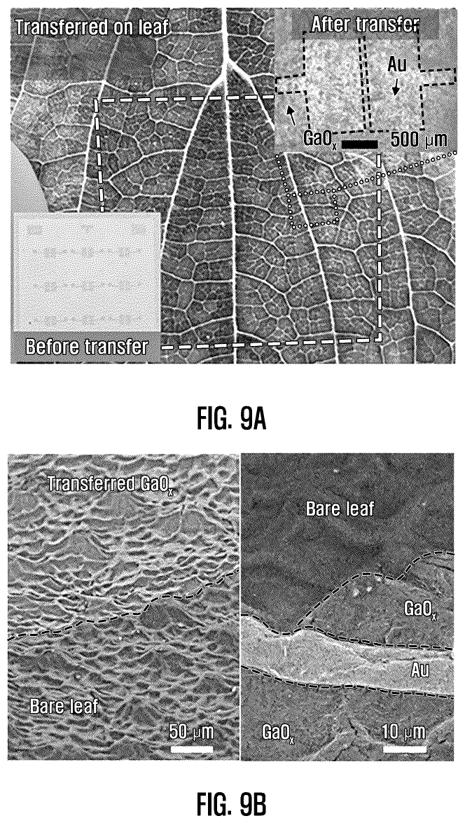

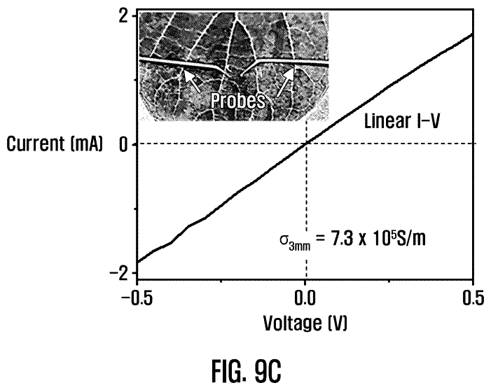

FIG. 9A is an optical image after transferring an ultrathin transparent circuit board onto a leaf according to an embodiment of the present disclosure.

Images inserted in FIG. 9A show the circuit lines before transferring (bottom left) and after transferring (magnified, top right).

FIG. 9B is a SEM image after transferring an ultrathin transparent circuit board onto a leaf according to an embodiment of the present disclosure.

Referring to FIG. 9B, it may be confirmed that the transferred circuit board is transferred along a surface of the leaf without any obvious cracks in the circuit lines due to its ultra-thinness (<10 nm).

FIG. 9C is an image illustrating conductivity of a circuit line of an ultrathin transparent circuit board that is transferred onto a leaf according to an embodiment of the present disclosure.

Referring to FIG. 9C, the conductivity of the transferred circuit line was 7.3×10⁵ S/m, which was similar to the conductivity of the circuit line before transfer.

### Experimental Example 7

A foldable and crumpleable display was manufactured using an LED by utilizing excellent foldability of a circuit board. The LED was mounted using eutectic gallium-indium alloy (E-GaIn) as solder.

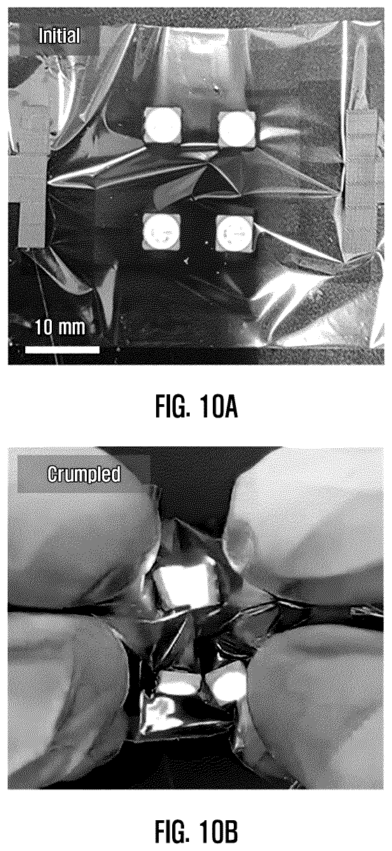

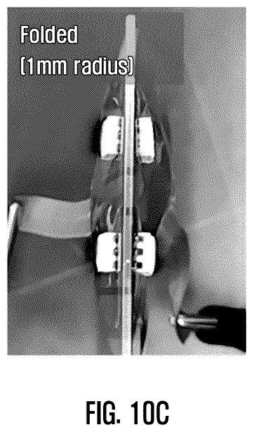

FIG. 10A is an optical image of a display manufactured using an LED manufactured according to an embodiment of the present disclosure, FIG. 10B is an optical image of a display manufactured using an LED manufactured according to an embodiment of the present disclosure when the display is crumpled, and FIG. 10C is an optical image of a display manufactured using an LED manufactured according to an embodiment of the present disclosure when the display is folded.

Referring to FIGS. 10A to 10C, the LED showed a stable operation without any change in light intensity when crumpled or folded.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

What is claimed is:

1. An ultrathin transparent electrode comprising:
metal oxide of a first metal;
an alloy of the first metal of the metal oxide and a second metal; and
the first metal of the metal oxide that is not bonded to the second metal.

2. The ultrathin transparent electrode of claim 1, wherein
the first metal comprises a liquid metal (LM), and
the LM comprises at least one selected from the group consisting of gallium (Ga), indium (In), tin (Sn), zinc (Zn), eutectic gallium-indium (EGaIn), gallium-aluminum (Ga—Al), gallium-tin (Ga—Sn), gallium-zinc (Ga—Zn), and gallium-aluminum (Ga—Al).

3. The ultrathin transparent electrode of claim 1, wherein the metal oxide comprises at least one selected from the group consisting of GaOx, Ga₂O₃, InOx, AlOx, SnO₂, and ZnO.

4. The ultrathin transparent electrode of claim 1, wherein the second metal comprises gold (Au), copper (Cu), or both.

5. The ultrathin transparent electrode of claim 1, wherein the ultrathin transparent electrode has a thickness of 500 μm or less.

6. The ultrathin transparent electrode of claim 1, wherein the ultrathin transparent electrode is configured as a single layer.

7. The ultrathin transparent electrode of claim 1, wherein the ultrathin transparent electrode is amorphous.

8. The ultrathin transparent electrode of claim 1, wherein the ultrathin transparent electrode has a sheet resistance of 30 Ω/sq to 1,000 Ω/sq, and the ultrathin transparent electrode has optical transparency of 85% to 99%.

9. A method of manufacturing an ultrathin transparent electrode, the method comprising:
preparing a metal oxide thin film of a first metal;
depositing a second metal on the metal oxide thin film; and
annealing the metal oxide thin film on which the second metal is deposited.

10. The method of claim 9, wherein
the first metal comprises a liquid metal (LM),
the LM comprises at least one selected from the group consisting of gallium (Ga), indium (In), tin (Sn), zinc (Zn), eutectic gallium-indium (EGaIn), gallium-aluminum (Ga—Al), gallium-tin (Ga—Sn), gallium-zinc (Ga—Zn), and gallium-aluminum (Ga—Al),
the metal oxide comprises at least one selected from the group consisting of GaOx, Ga₂O₃, InOx, AlOx, SnO₂, and ZnO, and
the second metal comprises gold (Au), copper (Cu), or both.

11. The method of claim 9, wherein the preparing of the metal oxide thin film of the first metal comprises:
filling a first metal into a printer head including two glass substrates spaced apart from each other; and
preparing the metal oxide thin film of the first metal by moving the printer head on a substrate along a longitudinal direction of the substrate.

12. The method of claim 11, wherein, in the preparing of the metal oxide thin film of the first metal, an upper metal oxide layer and a lower metal oxide layer are formed respectively on an upper portion where the first metal filled between the two glass substrates of the printer head comes out of the printer head and contacts the air and a lower portion where the first metal comes out of the printer head and contacts the substrate, and an LM layer containing a residual LM is interposed between the upper metal oxide layer and the lower metal oxide layer.

13. The method of claim 9, wherein the preparing of the metal oxide thin film of the first metal is performed by at least one method selected from the group consisting of atomic layer deposition (ALD), molecular beam epitaxy (MBE), pulsed laser deposition (PLD), and sputtering.

14. The method of claim 13, wherein a proportion of a metal layer in the metal oxide thin film is in excess of 18% or more.

15. The method of claim 9, wherein the depositing of the second metal on the metal oxide thin film is performed at a temperature of 10° C. to 200° C. and a pressure range of 10⁻⁵ torr to 10⁻⁷ torr.

16. The method of claim 11, wherein, in the preparing of the metal oxide thin film of the first metal, a speed of moving the printer head on the substrate along the longitudinal direction of the substrate is 0.001 mm/s to 5 mm/s.

17. The method of claim 9, wherein the depositing of the second metal on the metal oxide thin film comprises partially depositing a metal patterned through a mask.

18. The method of claim 9, wherein the annealing of the metal oxide thin film on which the second metal is deposited is performed at a temperature of 50° C. to 1,500° C. and a pressure range of 760 torr to 10⁻⁷ torr.

19. The method of claim 9, wherein the metal is formed, by the annealing, as a single layer comprising an alloy of the first metal of the metal oxide and the second metal, the metal oxide, and the first metal of the metal oxide that is not bonded to the second metal.

20. An electronic device comprising the ultrathin transparent electrode of claim 1.
